(19) United States
(12) Patent Application Publication
(10) Pub. No.: US 2024/0413152 A1
(43) Pub. Date: Dec. 12, 2024

(54) MULTI-VT SOLUTION FOR BOTTOM AND TOP TIER DEVICE

(71) Applicant: Taiwan Semicoductor Manufacturing Co., Ltd., Hsinchu (TW)

(72) Inventors: Hsueh-Ju Chen, Taipei City (TW); Tsung-Da Lin, Hsinchu (TW); Chi On Chui, Hsinchu (TW)

(21) Appl. No.: 18/469,049

(22) Filed: Sep. 18, 2023

Related U.S. Application Data
(60) Provisional application No. 63/507,187, filed on Jun. 9, 2023.

(51) Int. Cl. H01L 27/092; H01L 21/8238; H01L 29/06; H01L 29/423; H01L 29/775; H01L 29/786

(52) U.S. Cl. CPC H01L 27/092; H01L 21/823857; H01L 29/0673; H01L 29/42392; H01L 29/775; H01L 29/78696

(57) ABSTRACT

A method includes forming a transistor, which includes forming a semiconductor nanostructure, forming an interfacial layer encircling the semiconductor region, depositing a dipole film on the interfacial layer, depositing a high-k dielectric layer on the dipole film, and depositing a gate electrode on the high-k dielectric layer. The formation of the transistor may be free from dipole dopant drive-in process and may be free from dipole film removal process.

### PRIORITY CLAIM AND CROSS-REFERENCE

This application claims the benefit of the following provisionally filed U.S. patent application: Application No. 63/507,187, filed on Jun. 9, 2023, and entitled “MULTI-VT SOLUTION FOR BOTTOM AND TOP TIER DEVICE,” which application is hereby incorporated herein by reference

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17 illustrate the views of intermediate stages in the formation of a Complementary Field-Effect Transistor (CFET) including a dipole dopant(s) doped therein in accordance with some embodiments.

FIGS. 18-22 illustrate the views of intermediate stages in the formation of gate stacks including a dipole film in accordance with some embodiments.

FIGS. 23-27 illustrate the views of intermediate stages in the formation of gate stacks including a dipole film in accordance with some embodiments.

FIGS. 28 and 29 illustrate the distribution profiles of dipole dopants in gate stacks in accordance with some embodiments.

FIG. 30 illustrates a process flow for forming a CFET in accordance with some embodiments.

FIG. 31 illustrates a process flow for selectively doping a dipole dopant into a gate stack in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of selectively doping dipole dopants into a gate stack of a Complementary Field-Effect Transistor (CFET) and the respective CFET structure are provided. In accordance with some embodiments of the present disclosure, interfacial layers (ILs) are formed on a first and a second semiconductor region, each for forming a transistor. A dipole film is formed on the ILs. The dipole film is selectively removed from the second semiconductor region and left in the first semiconductor region. High-k gate dielectrics are then formed, followed by the formation of gate electrodes to form gate stacks of a first transistor and a second transistor, which have different threshold voltages due to different dipole doping. There is no dipole drive-in process and no dipole film removal process performed. Accordingly, the thermal budget that would be used by the drive-in process is saved. Manufacturing cost is also reduced. Although Gate-All-Around (GAA) transistors are used in the CFET as examples, the embodiments of the present disclosure may be applied to other types of transistors such as Fin Field-Effect Transistors (FinFETs), planar transistors, or the like.

In the formation of the gate stacks Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

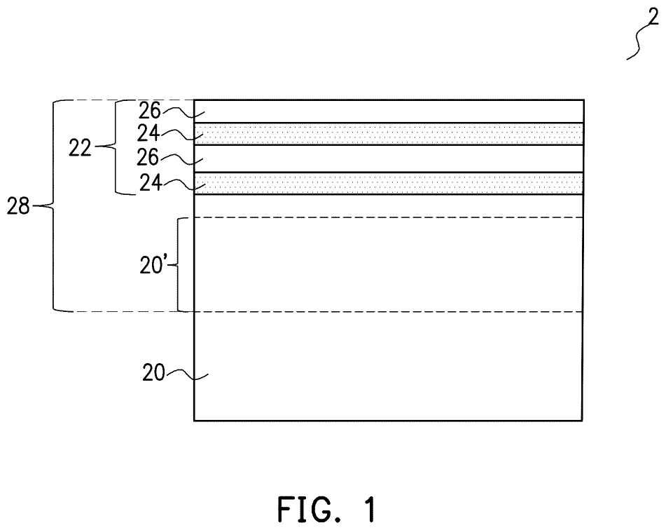

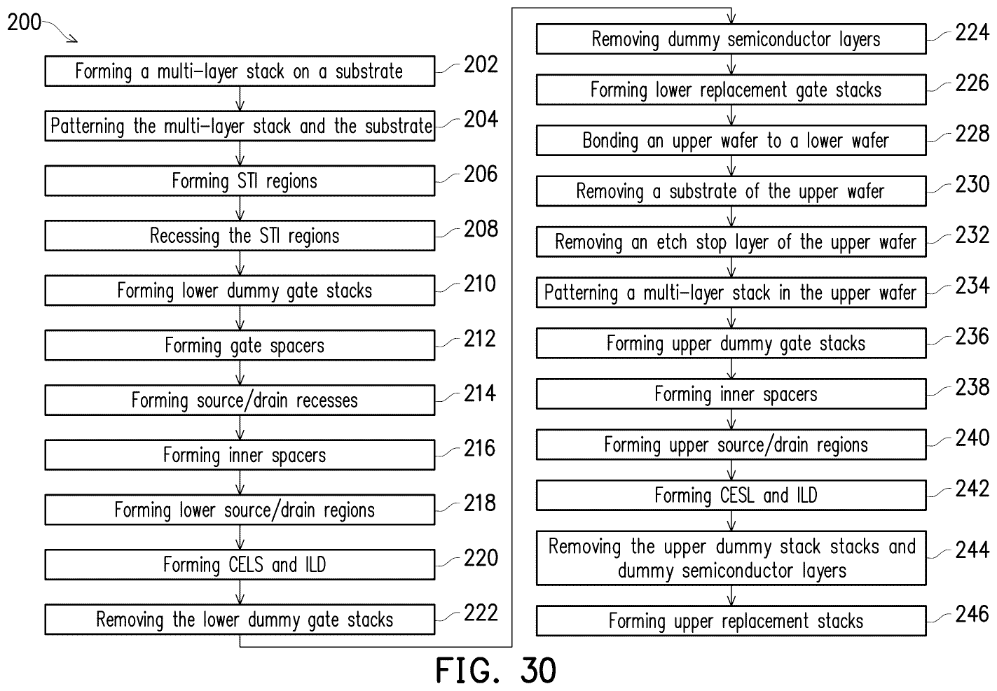

FIGS. 1 through 17 illustrate the cross-sectional views of intermediate stages in the formation of a Complementary Field-Effect Transistor (CFET), which includes an upper transistor stacked on a lower transistor in accordance with some embodiments of the present disclosure. The corresponding processes are also reflected schematically in the process flow 200 shown in FIG. 30.

Referring to FIG. 1, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. Other substrates, such as a multi-layered or gradient substrate may also be used. In some embodiments, the semiconductor material of the substrate 20 may include Si, SiGe, Ge, GaAs, InSb, GaSb, InAlAs, InGaAs, GaSbP, GaAsSb, or the like, or combinations thereof. A multi-layer stack 22 is formed over the substrate 20. The respective process is illustrated as process 202 in the process flow 200 as shown in FIG. 30. The multi-layer stack 22 includes alternating dummy semiconductor layers 24 and semiconductor layers 26. In the illustrated example, the multi-layer stack 22 includes two of the dummy semiconductor layers 24 and two of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), and deposited by a process such as Chemical Vapor Deposition (CVD), Atomic Layer deposition (ALD), Low Pressure CVD (LPCVD), Ultra High Vacuum CVD (UHVCVD), Reduced Pressure CVD (RPCVD), or the like.

The dummy semiconductor layers 24 are formed of a first semiconductor material. The semiconductor layers 26 are formed of a second semiconductor material different from the first semiconductor material. The first and the second semiconductor materials, while different from each other, may be selected from the candidate semiconductor materials of the substrate 20. In accordance with some embodiments, dummy semiconductor layers 24 may be formed of or comprise silicon germanium, and semiconductor layers 26 may be formed of silicon or silicon germanium that has a lower germanium atomic percentage than semiconductor layer 24.

In accordance with some embodiments, a bottom one of the dummy semiconductor layers 24 is deposited on the bulk semiconductor substrate 20 through epitaxy, followed the deposition of a semiconductor layer 26, also through epitaxy. Once the semiconductor layer 26 has been formed over dummy semiconductor layer 24, the deposition process is repeated to form the remaining alternating layers in multilayer stack 22, until a desired topmost layer of multilayer stack 22 has been formed. In accordance with some embodiments, dummy semiconductor layers 24 have thicknesses the same as or similar to each other, and semiconductor layers 26 have thicknesses the same as or similar to each other. Dummy semiconductor layers 24 may also have the same thicknesses as, or different thicknesses from, that of semiconductor layers 26. In accordance with some embodiments, dummy semiconductor layers 24 are removed in the subsequent processes, and are alternatively referred to as sacrificial layers 24.

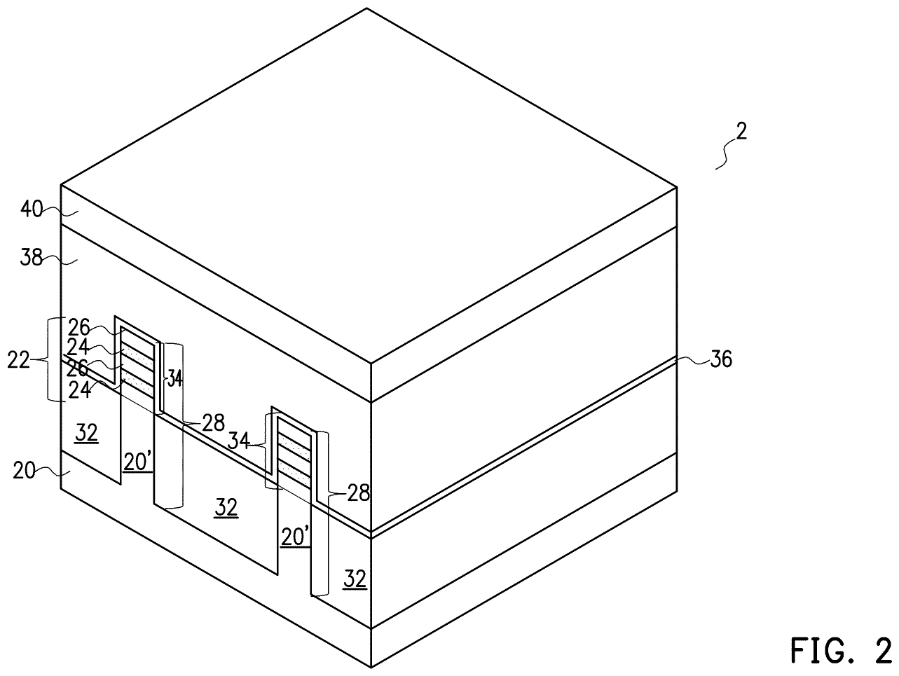

In a subsequent process, as shown in FIG. 2, which shows a perspective view of the structure, multi-layer stack 22 and substrate 20 are patterned to form semiconductor strips 28. The respective process is illustrated as process 204 in the process flow 200 as shown in FIG. 30. In accordance with some embodiments, there are some pad oxide layer(s) and hard mask layer(s) (not shown) formed over multilayer stack 22. These layers are patterned, and are used for the patterning of multilayer stack 22.

Each of semiconductor strips 28 includes semiconductor strip 20′ (the portions of the original substrate 20) and the remaining portions of multi-layer stack 22. The remaining portions of the semiconductor layers 26 may also be referred to as semiconductor nanostructures hereinafter. Accordingly, multi-layer stacks 22 include dummy semiconductor layers 24 and semiconductor nanostructures 26. The patterning is performed through etching, which may be performed by any acceptable etch process, such as a Reactive Ion Etch (RIE), Neutral Beam Etch (NBE), the like, or a combination thereof. The etching may be anisotropic.

The semiconductor strips and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process.

Isolation regions 32 (also referred to STI regions 32) are formed over the substrate 20 and between adjacent semiconductor strips 28. The respective process is illustrated as process 206 in the process flow 200 as shown in FIG. 30. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the isolation regions 32 include silicon oxide formed by an FCVD process, followed by an anneal process.

Isolation regions 32 are then recessed. The respective process is also illustrated as process 208 in the process flow 200 as shown in FIG. 30. Some upper portions of semiconductor strips 28 (including multi-layer stacks 22) protrude higher than the remaining isolation regions 32 to form protruding fins 34.

As also illustrated in FIG. 2, dummy dielectric layer 36 is formed on the protruding fins 34. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a Chemical Mechanical Polish (CMP) process or a mechanical polish process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer(s) 40 is formed over the planarized dummy gate layer 38, and may include, for example, silicon nitride, silicon oxynitride, or the like.

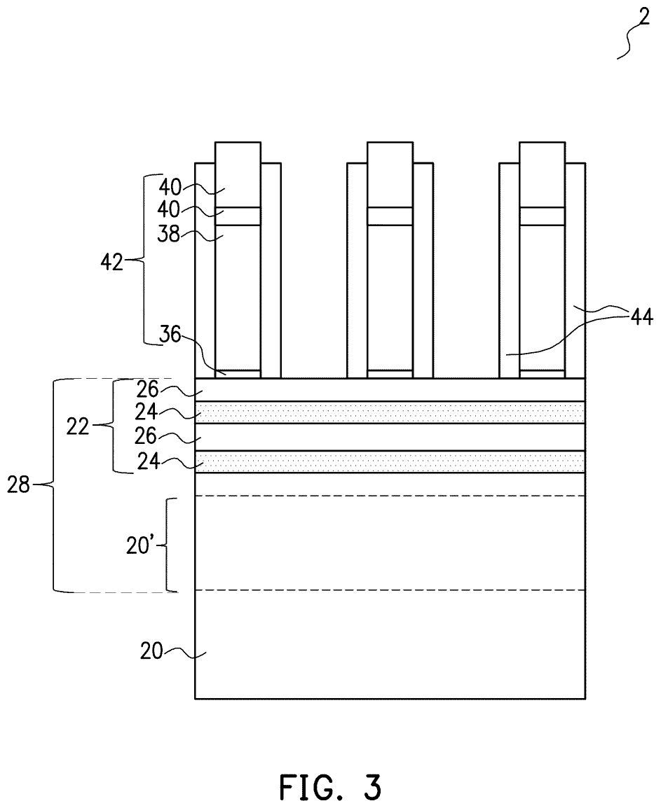

Next, the mask layer 40 is patterned through photolithography and etching processes to form an etching mask, which is then used to etch and pattern dummy gate layer 38, and possibly dummy dielectric layer 36. A resulting structure is shown in FIG. 3, which illustrates a vertical cross-section along the lengthwise direction of semiconductor strip 28. The remaining portions of mask layer 40, dummy gate layer 38, and dummy dielectric layer 36 form dummy gate stacks 42, which includes masks 40, dummy gate electrodes 38, and dummy gate dielectrics 36. The respective process is illustrated as process 210 in the process flow 200 as shown in FIG. 30.

As also shown In FIG. 3, gate spacers 44 are formed over the multi-layer stacks 22 and on exposed sidewalls of dummy gate stacks 42. The respective process is illustrated as process 212 in the process flow 200 as shown in FIG. 30. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 are also formed.

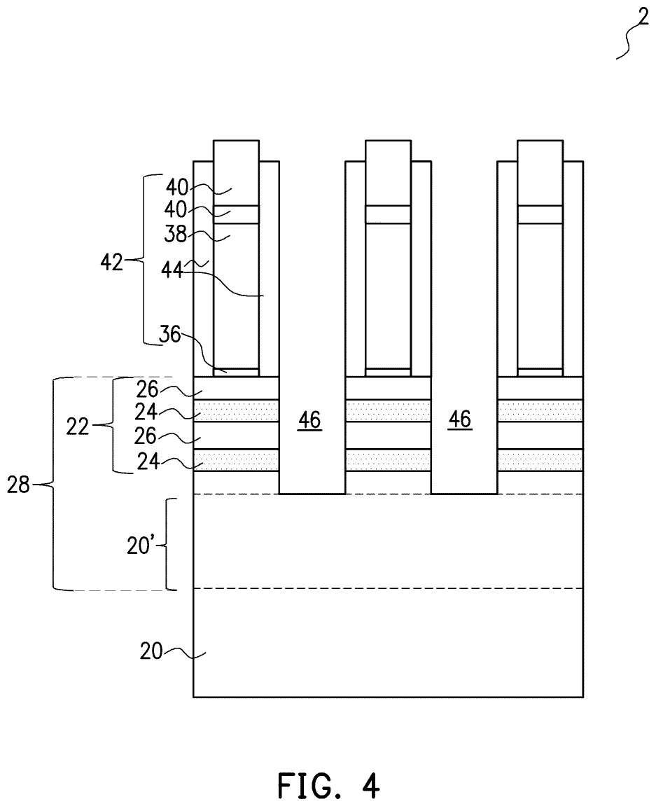

Next, as shown in FIG. 4, source/drain recesses 46 are formed in semiconductor strips 28. The respective process is illustrated as process 214 in the process flow 200 as shown in FIG. 30. The source/drain recesses 46 are formed through etching, and may extend through the multi-layer stacks 22 and into the semiconductor strips 20′. The bottom surfaces of the source/drain recesses 46 may be at a level above, below, or level with the top surfaces of the isolation regions 32 (in a different plane). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

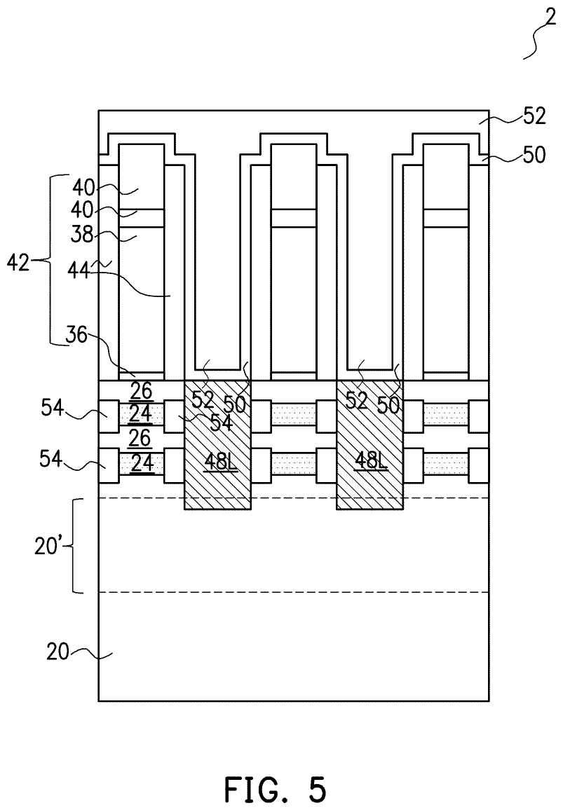

In FIG. 5, inner spacers 54 are formed. The respective process is illustrated as process 216 in the process flow 200 as shown in FIG. 30. The formation of inner spacers 54 may include an etching process that laterally etches (and recesses) the dummy semiconductor layers 24 (FIG. 4) to form lateral recesses from the opposite edges of semiconductor layers 26. The etching process may be isotropic and may be selective to semiconductor nanostructures 26, so that semiconductor nanostructures 26 is substantially unetched.

In some embodiments where the dummy semiconductor layers 24 are formed of silicon germanium and the semiconductor nanostructures 26 are formed of silicon free from germanium, the etch process may comprise a dry etch process using a chlorine gas, with or without a plasma. Because the dummy gate stacks 42 are in contact with the opposing sidewalls of the semiconductor nanostructures 26 (see FIG. 2 for reference), the dummy gate stacks 42 may support the upper semiconductor nanostructures 26 so that the semiconductor nanostructures 26 do not collapse upon removal of the dummy semiconductor layers 24. Further, although the sidewalls of the dummy semiconductor layers 24 are illustrated as being straight after the etching, the sidewalls may be concave or convex.

After the lateral recesses are formed, an insulating material is conformally deposited, followed by the etching of the insulating material to leave behind inner spacers 54. The insulating material may be a silicon-containing dielectric material such as silicon oxycarbonitride, silicon oxycarbide, silicon oxynitride, or the like. The deposition of the insulating material may be achieved through a conformal deposition process such as ALD, CVD, or the like. The etching of the insulating material may be anisotropic or isotropic. The insulating material, when etched, has portions remaining in the lateral recesses, hence forming the inner spacers 54.

Further referring to FIG. 5, lower epitaxial source/drain regions 48L are formed. The respective process is illustrated as process 218 in the process flow 200 as shown in FIG. 30. The lower epitaxial source/drain regions 48L are formed in the lower portions of the source/drain recesses 46, and are in contact with the lower semiconductor nanostructures 26. Inner spacers 54 electrically insulate the lower epitaxial source/drain regions 48L from the dummy semiconductor layers 24.

The lower epitaxial source/drain regions 48L are epitaxially grown, and have a conductivity type that is suitable for the device type (p-type or n-type) of the lower transistor. When lower epitaxial source/drain regions 48L are n-type source/drain regions, the respective material may include silicon or carbon-doped silicon, which is doped with an n-type dopant such as phosphorous, arsenic, or the like. When lower epitaxial source/drain regions 48L are p-type source/drain regions, the respective material may include silicon or silicon germanium, which is doped with a p-type dopant such as boron, indium, or the like. The lower epitaxial source/drain regions 48L may be in-situ doped, and may be, or may not be, implanted with the corresponding p-type or n-type dopants.

Contact Etch Stop Layer (CESL) 50 and Inter-Layer Dielectric (ILD) 52 are formed over the lower epitaxial source/drain regions 48L. The respective process is illustrated as process 220 in the process flow 200 as shown in FIG. 30. The CESL 50 may be formed of a dielectric material having a high etching selectivity from the etching of the ILD 52, such as silicon nitride, silicon oxide, silicon oxynitride, or the like, and may be formed by a conformal deposition process, such as CVD, ALD, or the like. The ILD 52 is formed of a dielectric material, which may be deposited by any suitable method, such as CVD, plasma-enhanced CVD (PECVD), FCVD, or the like. The applicable dielectric material of the ILD 52 may include phospho-silicate glass (PSG), boro-silicate glass (BSG), boron-doped phospho-silicate glass (BPSG), undoped silicate glass (USG), silicon oxide, or the like.

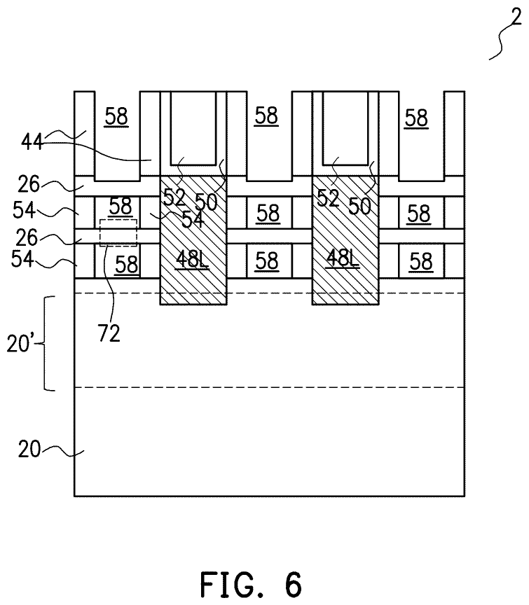

A planarization process is then for removing excess portions of CESL 50 and ILD 52, so that the top surfaces of 50 and ILD 52 are coplanar with the top surfaces of gate spacers 44 and dummy gate stacks 42. The planarization process may be stopped on gate electrodes 38, or may stop on one hard mask 40. The dummy gate stacks 42 are then removed in one or more etching processes, so that recesses 58 are formed, as shown in FIG. 6. The respective process is illustrated as process 222 in the process flow 200 as shown in FIG. 30. Each of recesses 58 exposes and/or overlies portions of multi-layer stacks 22′ (refer to FIG. 5).

The remaining portions of the dummy semiconductor layers 24 are then removed through etching, so that recesses 58 extend between the semiconductor nanostructures 26. The respective process is illustrated as process 224 in the process flow 200 as shown in FIG. 30. In the etching process, the dummy semiconductor layers 24 are etched at a faster rate than the semiconductor nanostructures 26, with the inner spacers 54 unetched. The etching may be isotropic. For example, when the dummy semiconductor layers 24 are formed of silicon-germanium, the etch process may include a wet etch process using tetramethylammonium hydroxide (TMAH), ammonium hydroxide (NH₄OH), or the like.

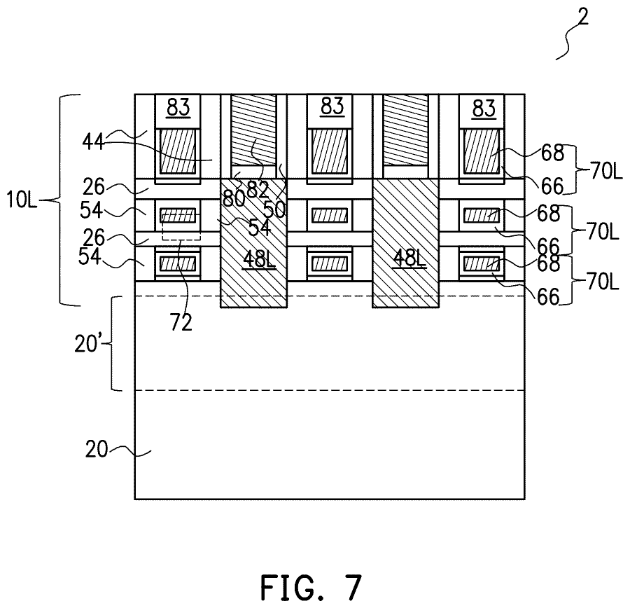

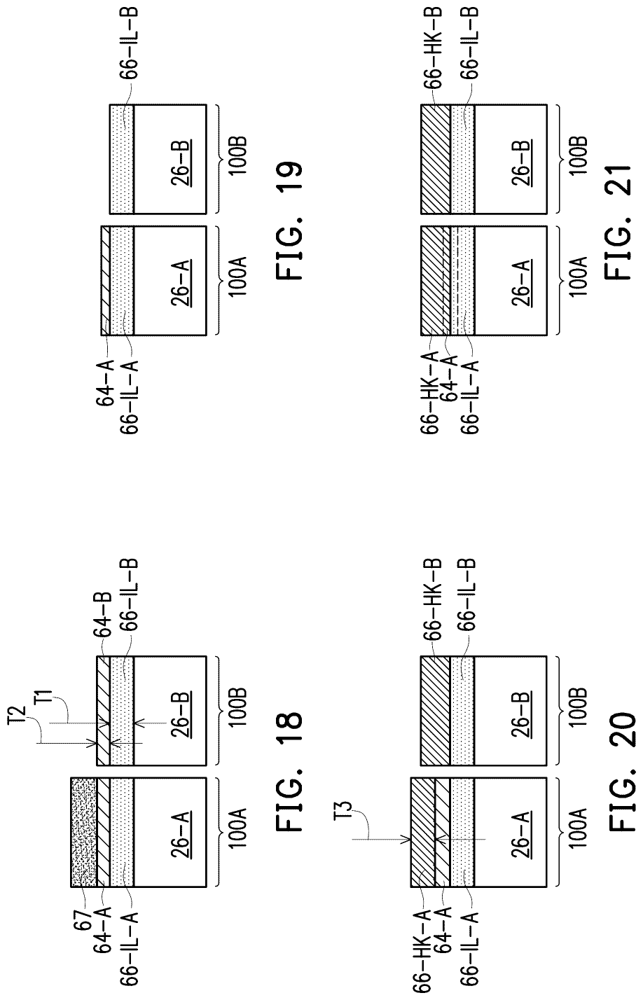

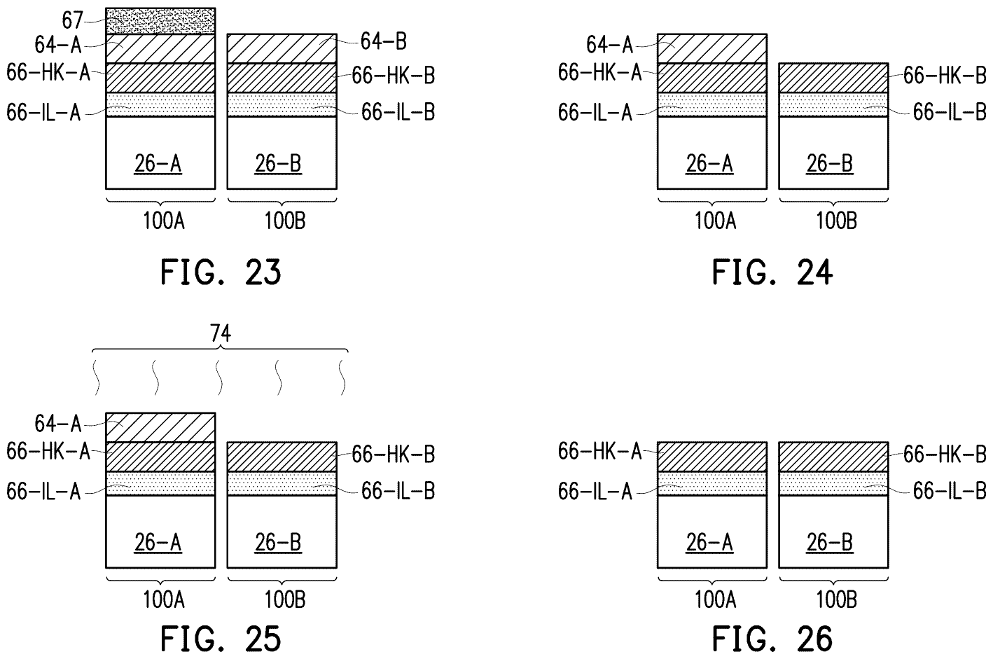

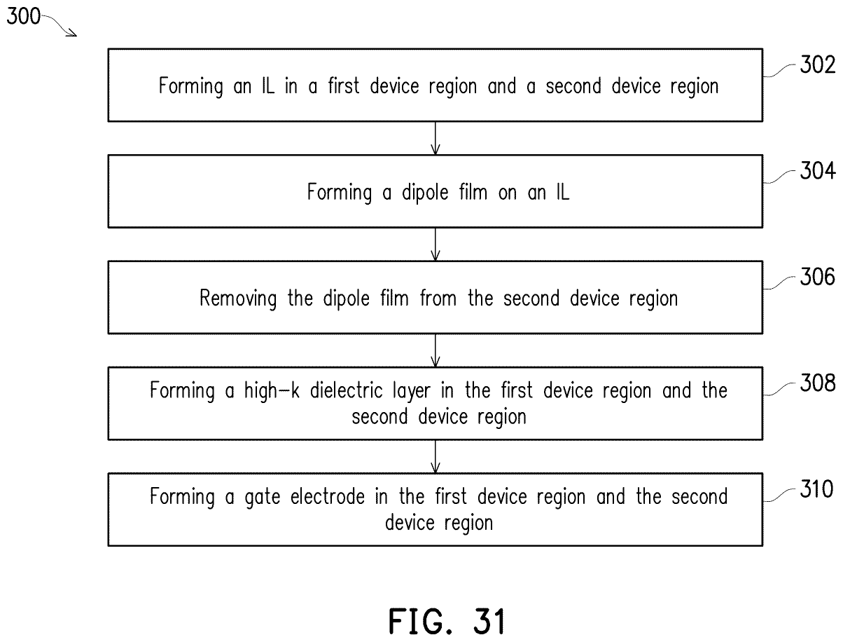

Referring to FIG. 7, replacement gate stacks 70L are formed in recesses 58. The respective process is illustrated as process 226 in the process flow 200 as shown in FIG. 30. In accordance with some embodiments, the process 226 is also the process 300 as shown in FIG. 31, which also includes the processes shown in FIGS. 18-22. In accordance with alternative embodiments, the process 226 may include the processes shown in FIGS. 23-27. Replacement gate stacks 70L include gate dielectrics 66 and gate electrodes 68. The gate dielectrics 66 are formed on the exposed surfaces of semiconductor nanostructures 26 and gate spacers 44. The gate dielectrics 66 wrap around (encircle) all (e.g., four) sides of the semiconductor nanostructures 26.

FIGS. 18-22 and FIGS. 23-27 illustrate some example detailed views of some processes that may be adopted for forming replacement gate stacks 70L in accordance with some embodiments. The processes shown in FIGS. 18-22 differ from the processes shown in FIGS. 23-27 in that in the processes shown in FIGS. 18-22, dipole film is formed between IL and the overlying high-k dielectric layer, with no drive-in process and no dipole-film removal process being performed. In the processes shown in FIGS. 23-27, on the other hand, the dipole film is formed over a high-k dielectric layer, followed by a drive-in process and a dipole-film removal process.

Referring to FIG. 18, device regions 100A and 100B are illustrated side-by-side, each for forming a transistor. The structures in each of device region 100A and device region 100B may be obtained from the corresponding regions such as regions 72 in FIGS. 6 and 7. The features illustrated in device regions 100A and 100B may be distinguished from each other by adding letter “A” or “B,” respectively, to distinguish the device regions they are in. The like-features with the same reference number (but with different suffixes A and B) may be formed in a common process or different formation processes. Each of the device regions 100A and 100B may be a pMOS region used for forming a p-type transistor, or an nMOS region used for forming an n-type transistor.

Referring again to FIG. 18, semiconductor nanostructures 26 (including 26-A and 26-B) are formed in device regions 100A and 100B, respectively. It is appreciated that although semiconductor nanostructures 26-A and 26-B are shown as being placed side-by-side, they may be obtained from the regions that are close to, but not in contact with each other, as may be realized from the structure shown FIG. 7.

ILs 66-IL-A and 66-IL-B are formed on, and may wrap around, semiconductor nanostructures 26-A and 26-B, respectively. The respective process is illustrated as process 302 in the process flow 300 as shown in FIG. 31. ILs 66-IL-A and 66-IL-B may include an oxide layer such as a silicon oxide layer, which may be formed through the thermal oxidation of the surface parts of semiconductor nanostructures 26-A and 26-B, a chemical oxidation process, or a deposition process. ILs 66-IL-A and 66-IL-B may be formed in a common process or separate processes. Accordingly, the thickness of IL 66-IL-A may be equal to, greater than, or smaller than the thickness of IL 66-IL-B, and/or the material of IL 66-IL-A may be the same as or different from the material of IL 66-IL-B.

Dipole film 64 is formed, and includes portion 64-A on IL 66-IL-A, and portion 64-B on IL 66-IL-B. The respective process is illustrated as process 304 in the process flow 300 as shown in FIG. 31. Dipole film 64 may be an n-type dipole film comprising an n-type dipole dopant. The n-type dipole dopant may include La, Sc, Er, Sr, Y, and/or the like, or combinations thereof. Conversely, dipole film 64 may be a p-type dipole film comprising a p-type dipole dopant such as Al, Zn, Nb, and/or the like, or combinations thereof. Dipole film 64 may include a compound of the dipole dopant, which compound may be an oxide, a nitride, and/or an oxynitride of the n-type or the p-type dipole dopant. The compound may also be a metal compound.

In accordance with some embodiments, dipole film 64 is deposited as a very thin film, which may have the thickness T2 smaller than about 10 Å. Thickness T2 may also be in the range between about 1 Å and about 10 Å, or may be smaller than about 1 Å. Furthermore, thickness T2 of dipole film 64 may be smaller than 50 percent of the thicknesses T1 of ILs 66-IL-A and 66-IL-B, and also smaller than 50 percent of the thickness T3 (FIG. 20 of the overlying high-k dielectric layers 66-HK-A and 66-HK-B.

The formation process of dipole film 64 may include a conformal deposition process such as Atomic Layer deposition (ALD), plasma enhanced ALD, or the like. The process gases may include a precursor, a reactant, and a dilute gas. For example, when the dipole dopant comprises La, the respective precursor may include La(thd)₃, La(fAMD)₃, La(Cp)₃, La(iPrCP)₃, or the like, or combinations thereof. The reactant may include H₂O, O₃, O₂, NH₃, H₂, or the like, or combinations thereof. A dilute gas may be added, and may include N₂, Ar, H₂, or the like, or combinations thereof. The deposition temperature may be in the range between about 100° C. and about 500° C. The pressure of the deposition chamber may be in the range between about 0.1 Torr and about 100 Torr.

Further referring to FIG. 18, etching mask 67 is deposited on dipole film 64. In accordance with some embodiments, etching mask 67 is a hard mask, which may be a dielectric hard mask formed of or comprising silicon nitride, silicon oxynitride, silicon oxy-carbide, or the like. Etching mask 67 may also be a metal hard mask comprising titanium nitride, tantalum nitride, tungsten nitride, titanium carbide, tantalum carbide, tungsten carbide, or the like. Alternatively, etching mask 67 may be a photoresist layer. Etching mask 67 is formed on dipole films 64 and in both of device regions 100A and 100B, and is then patterned and removed from device region 100B.

FIG. 19 illustrates the etching of dipole film 64-B from device region 100B, for example, by using the etching mask 67 to define patterns. The respective process is illustrated as process 306 in the process flow 300 as shown in FIG. 31. In device region 100A, the portion 64-A of the dipole film 64 remains, and is in contact with IL 66-IL-A. In device region 100B, IL 66-IL-B is exposed.

In a subsequent process, as shown in FIG. 20, high-k dielectric layer 66-HK, which includes high-k dielectric layers 66-HK-A and 66-HK-B, are deposited. The respective process is illustrated as process 308 in the process flow 300 as shown in FIG. 31. The materials of high-k dielectric layers 66-HK-A and 66-HK-B may be selected from hafnium oxide, zirconium oxide, lanthanum oxide, and/or the like, combinations thereof, and/or composite layers thereof.

In accordance with some embodiments, during an entire period of time starting from the time dipole film 64 starts to be deposited (FIG. 19) and ending at the time high-k dielectric layers 66-HK-A and 66-HK-B starts to be deposited, no anneal process is performed, which is also a drive-in process for driving the dipole dopant in dipole film 64-A into IL 66-IL-A. In accordance with some embodiments, during an entire period of time starting from the time dipole film 64 starts to be deposited (FIG. 19) and ending at the time gate stacks 52A and 52B have been formed, no annealing for driving the dipole dopant in dipole film 64-A into IL 66-IL-A (and possibly the overlying high-k dielectric layer 66-HK-A) is performed. It is appreciated that some deposition processes may be performed at elevated temperatures, while in accordance with some embodiments, no annealing process that does not result in the deposition of any layer is performed. Furthermore, there is no removal process for removing the dipole film 64-A.

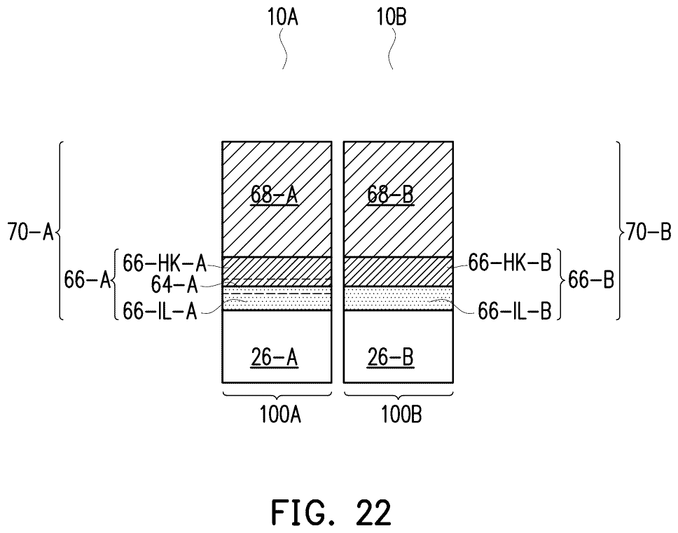

FIG. 21 schematically illustrates the inter-diffusion of IL 66-IL-A, dipole film 64-A, and 66-HK-A in accordance with some embodiments. It is appreciated that the inter-diffusion may occur at the time high-k dielectric layers 66-HK-A and 66-HK-B are deposited if they are deposited at a high temperature, or may occur at a later time such as in the deposition of gate electrodes or in subsequent thermal formation processes, packaging processes, and high-temperature storage. Since dipole film 64-A is thin and/or the temperature of the subsequent processes is high, dipole film 64-A is diffused into IL 66-IL-A and high-k dielectric layer 66-HK-A, and is no longer a separate film, except that in this region, the dipole dopant has a peak concentration, which indicates where the dipole film 64-A was located, as illustrated using dashed lines. Accordingly, the threshold voltage of the resulting transistor 10A (FIG. 22) due to the incorporation of the dipole dopant into the respective gate dielectric.

Referring to FIG. 22, gate electrodes 68-A and 68-B (collectively referred to as gate electrodes 68) are formed on gate dielectric 66-A and gate dielectric 66-B, respectively. The respective process is illustrated as process 310 in the process flow 300 as shown in FIG. 31. Gate stacks 70-A and 70-B are thus formed in device regions 100A and 100B, respectively. In accordance with some embodiments, the respective transistors 10A and 10B in device regions 100A and 100B, respectively, are of the same conductivity type, and the portions of gate electrodes 68-A and 68-B may be formed in the common processes, and hence have the same structures and same materials. In accordance with alternative embodiments, the respective transistors in device regions 100A and 100B are of opposite conductivity types, and the portions of gate electrodes 68-A and 68-B may be formed in separate formation processes.

Each of gate electrodes 68-A and 68-B may include a work-function layer, and may or may not include a filling metal over the work-function layer. When the respective transistor in either one of device regions 100A and 100B is an n-type transistor, the corresponding work-function layer may be an n-type work-function layer having a low work function, and may include TiAlN, TiAl, TiAlC, TaAlC, TaAlN, or the like, or multi-layers thereof. Alternatively, when the respective transistor in either one of device regions 100A and 100B is an n-type transistor, the corresponding work-function layer may be a p-type work-function layer having a high work function, and may include TIN, TiSiN, TaN, WCN, MOCN or the like, or multi-layers thereof.

IL 66-IL-A, dipole film 64-A (which may or may not be a separate film, but is distinguishable from the concentration distribution of the dipole dopant), and high-k dielectric layers 66-HK-A collectively form gate dielectric 66-A, which further form gate stack 70-A with the gate electrode 68-A. IL 66-IL-B and high-k dielectric layers 66-HK-B collectively form gate dielectric 66-B, which further form gate stack 70-B with the gate electrode 68-B.

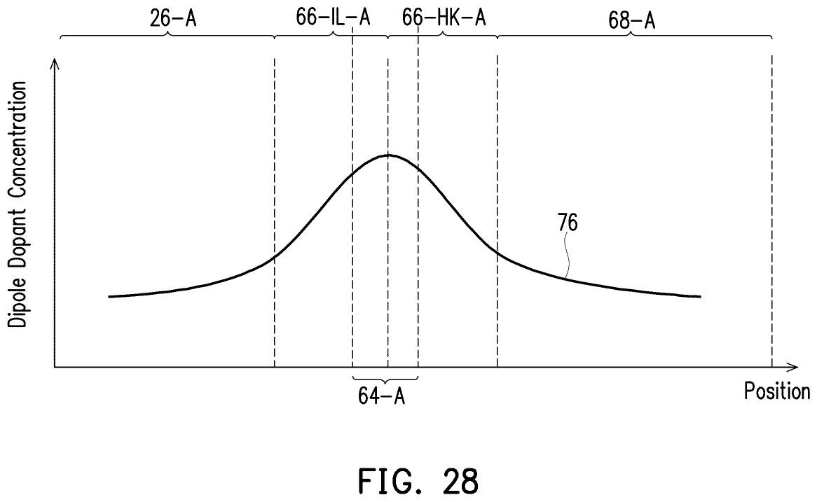

FIG. 28 illustrates the profile of the dipole dopant as line 76, with the profile generated due to the processes shown in FIGS. 18-22. The Y-axis illustrates the dipole dopant concentration, and the X-axis illustrates positions in the gate electrode. Since dipole film is very thin, and the dipole dopant is diffused from dipole film 64-A into high-k dielectric layer 66-HK-A and IL 66-IL-A, high-k dielectric layer 66-HK-A and IL 66-IL-A may be considered as being in contact with each other due to diffusion toward each other, and that dipole film 64-A may be considered to be fully diffused into high-k dielectric layer 66-HK-A and IL 66-IL-A. In which case, the peak dipole dopant concentration occurs at the interface between high-k dielectric layer 66-HK-A and IL 66-IL-A.

Alternatively, the high-dopant-concentration region may be considered as having the dipole dopant film 64-A therein, and the high-k dielectric layer 66-HK-A is separated from IL 66-IL-A by the dipole dopant film 64-A.

FIGS. 23-27 illustrate the cross-sectional views of intermediate stages in the formation of replacement gate stacks 70-L (FIG. 7) in accordance with some embodiments of the present disclosure. Unless specified otherwise, the materials, the structures, and the formation processes of the components in these embodiments are essentially the same as the like components denoted by like reference numerals in the embodiments in FIGS. 18-22. The details regarding the materials, the structures, and the formation processes provided in any of the embodiments throughout the description may be applied to any other embodiment whenever applicable.

Referring to FIG. 23, device regions 100A and 100B are provided. In device region 100A, IL 66-IL-A is formed over semiconductor nanostructure 26-A, high-k dielectric layer 66-HK-A is deposited over IL 66-IL-A, and dipole film 64-A is deposited over high-k dielectric layer 66-HK-A. In device region 100B, IL 66-IL-B is formed over semiconductor nanostructure 26-B, high-k dielectric layer 66-HK-B is deposited over IL 66-IL-B, and dipole film 64-B is deposited over high-k dielectric layer 66-HK-B. A patterned etching mask 67, which may be a hard mask patterned using a photoresist, or may be a photoresist, is then formed in device region 100A, and is removed from the device region 100B.

Referring to FIG. 24, dipole film 64-B is removed, for example, etched using etching mask 67 to define patterns. The etching mask 67 is then removed, for example, in an etching process or an ashing process.

Next, as shown in FIG. 25, anneal process 74 (also referred to as a dipole dopant drive-in process) is performed to drive the dipole dopants in the dipole films 64-A into the respective underlying high-k dielectric layer 66-HK-A and interfacial layer 66-IL-A. The anneal process 74 may be performed in a process gas such as N₂, He, NH₃, Ar, or the like, or the mixtures thereof. In accordance with some embodiments, anneal process 74 is performed through a soak anneal process, a spike rapid thermal anneal process, or the like.

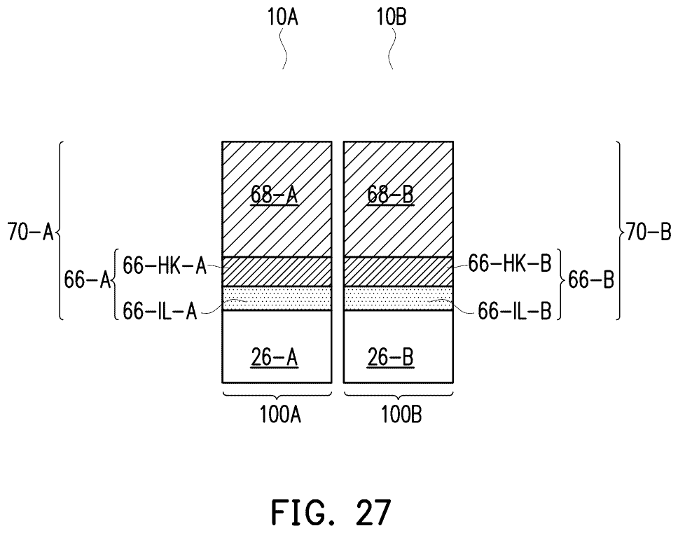

The anneal process 74 results in the dipole dopant in the dipole films 64-A to be driven into the respective underlying high-k dielectric layer 66-HK-A and IL 66-IL-A. Accordingly, the threshold voltage of the resulting transistor 10A (FIG. 27) is tuned. After the dipole dopant drive-in process, dipole film 64-A is removed, for example, in an etching process. The resulting structure is shown in FIG. 26. FIG. 27 illustrates the formation of gate electrodes 68-A and 68-B to finish the formation of gate stacks 70-A and 70-B and the corresponding transistors 10A and 10B.

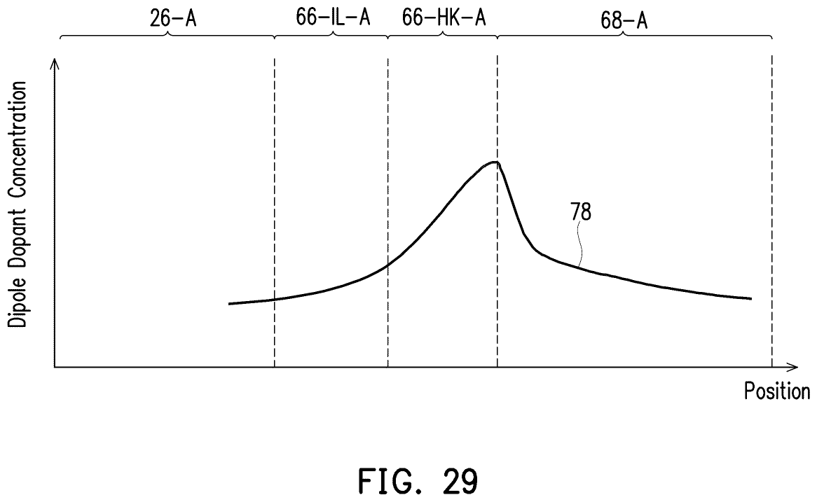

FIG. 29 illustrates the profile of the dipole dopant using line 78, with the profile generated due to processes shown in FIGS. 23-27. The Y-axis illustrates the dipole dopant concentration, and the X-axis illustrates positions. Since the dipole dopant is diffused from the dipole film 64-A that is over high-k dielectric layer 66-HK-A, and the dipole dopant film 64-A is later-on removed, the dipole dopant has a peak dopant concentration at the top surface of high-k dielectric layer 66-HK-A. Furthermore, since the dipole dopant will diffuse into gate electrode 68-A in future thermal processes or high-temperature storage, the profile of the dipole dopant in gate electrode 68-A may be steeper than in high-k dielectric layer 66-HK-A and IL 66-IL-A. Alternatively stated, the drop of the dipole dopant concentration per unit distance in high-k dielectric layer 66-HK-A and IL 66-IL-A is smaller than the drop of the dipole dopant concentration per unit distance in gate electrode 68-A.

Referring back to FIG. 7, the formed layers as shown in FIGS. 18-22 or FIGS. 23-27 are polished to remove excess portions higher than gate spacers 44, leaving behind replacement gate stacks 70L. Lower transistor 10L is thus formed. The illustrated lower transistor 10L may represent both of the transistors 10A and 10B (which co-exist in the same wafer/die) in FIG. 22 or FIG. 27.

After the formation of the replacement gate stacks 70L, the replacement gate stacks 70L are recessed in an etching process, followed by depositing a dielectric material into the respective recesses to form hard masks 83.

It is appreciated that regardless of whether the transistor in device region 100A is a p-type transistor or an n-type transistor, and regardless of whether the type of the work-function layer, the dipole film 64 may be a p-type dipole film or an n-type dipole film. When the transistor is a p-type transistor and the work-function layer is p-type, a p-type dipole dopant may reduce the threshold voltage Vt of the transistor, and an n-type dipole dopant may increase the threshold voltage Vt of the transistor. Conversely, when the transistor is an n-type transistor and the work-function layer is n-type, a p-type dipole dopant may increase the threshold voltage Vt of the transistor, and an n-type dipole dopant may reduce the threshold voltage Vt of the transistor.

In subsequent processes, the ILD 52 as shown in FIG. 6 is etched to form a contact opening. Source/drain silicide layers 80 (FIG. 7) is then formed, for example, through a self-aligned silicidation process. Gate contact plugs 82 are then formed. Gate contact plugs 82 may include an adhesion layer formed of TiN, and a filling metal formed of tungsten, cobalt, or the like.

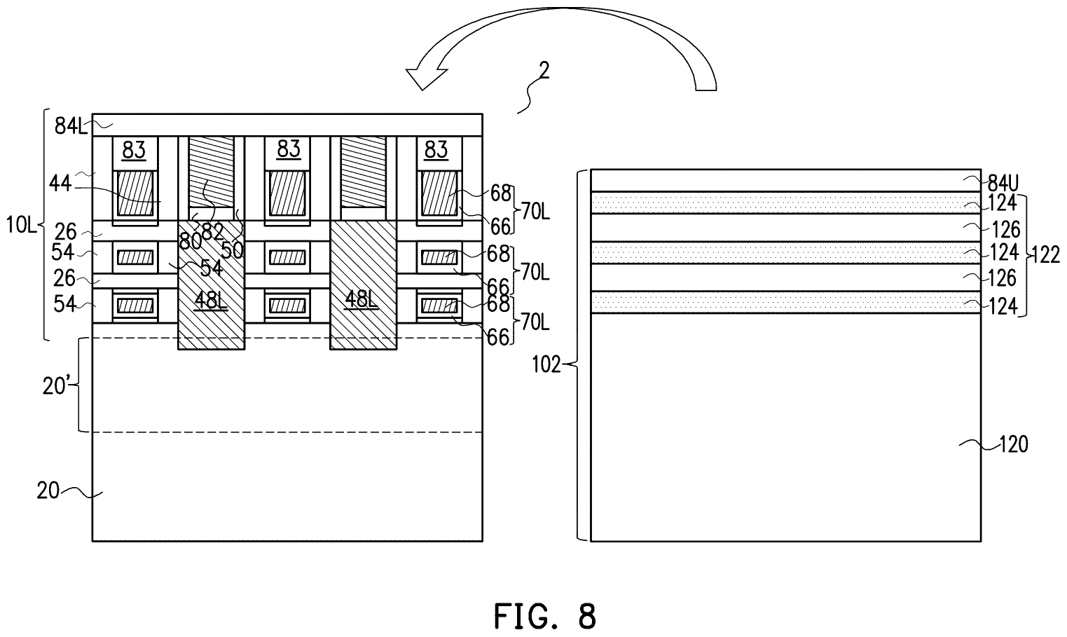

The wafer 2 as shown in FIG. 7 may be referred to as a lower wafer, and the corresponding transistors therein are also referred to as lower transistors 10L. FIGS. 8 through 17 illustrate the formation of upper wafer 102 and upper transistors 10U. Upper transistors U and the respective lower transistor 10U collectively form CFET transistors. The like features in FIGS. 8 through 17 are denoted using similar reference notations, except that the feature in upper wafer 102 may have number “1” added in front of the respective reference notations to indicate they are in the upper wafer. Unless specified otherwise, the corresponding materials, structures, and the formation processes in upper wafer 102 may be essentially the same as, and may be found from the discussions of the materials, structures, and the formation processes of their like features in the lower wafer 2.

Referring to FIG. 8, bond layer 84L is formed as a top surface layer of the lower wafer 2. In accordance with some embodiments, bond layer 84L is formed through a deposition process such as CVD, ALD, PECVD, or the like. A planarization process may be performed to level the top surface of bond layer 84L. Bond layer 84L may be formed of or comprise a silicon-containing dielectric material such as silicon oxide, silicon nitride, silicon oxynitride, silicon oxycarbide, silicon oxy carbonitride, or the like.

FIG. 8 also illustrates the formation of upper wafer 102, which includes substrate 120 and multi-layer stack 122 over substrate 120. The materials and the formation processes of substrate 120 and multi-layer stack 122 may be essentially the same as that of substrate 20 and multi-layer stack 22 as shown in FIG. 1, and the details are not repeated herein. The top layer in multi-layer stack 122 may be a dummy semiconductor layer 124, which may be formed of silicon germanium in accordance with some embodiments. Bond layer 84U is formed over multi-layer stack 122, and may also be formed of or comprise a silicon-containing dielectric material such as silicon oxide, silicon nitride, silicon oxynitride, silicon oxycarbide, silicon oxy carbonitride, or the like.

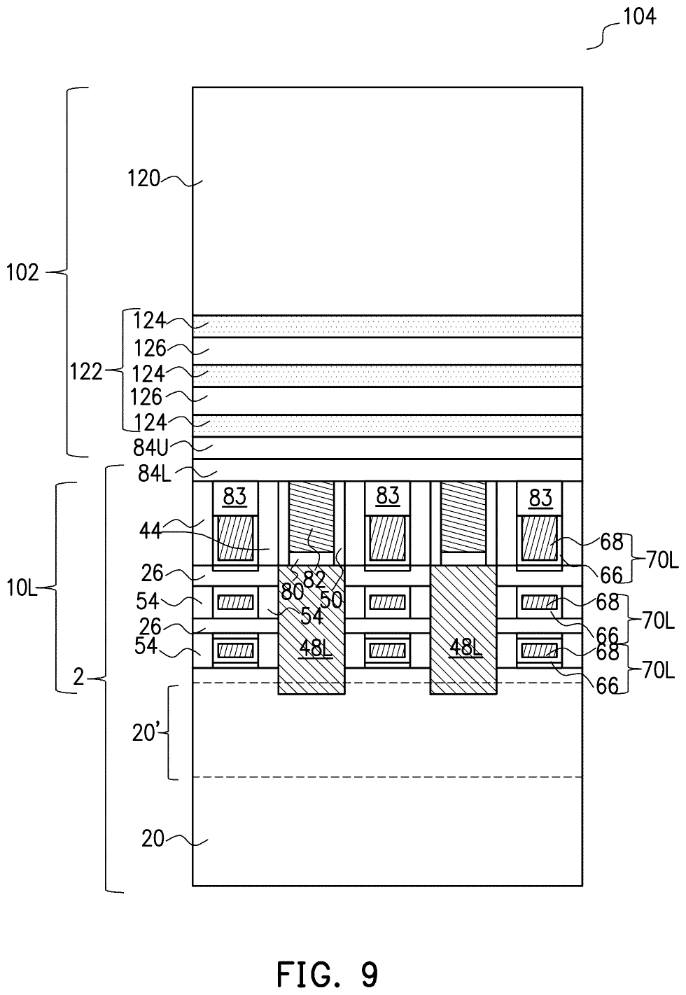

Upper wafer 102 is then flipped upside down, and is bonded to the underlying lower wafer 2 through the bonding of bond layer 84U to bond layer 84L. The respective process is illustrated as process 228 in the process flow 200 as shown in FIG. 30. The resulting composite wafer 104 is shown in FIG. 9. The bonding of bond layer 84U to bond layer 84L may be achieved through fusion bonding, for example, with Si—O—Si bonds being formed to join bond layer 84U to bond layer 84L.

Next, substrate 120 is removed, for example, through an anisotropic etching process. The respective process is illustrated as process 230 in the process flow 200 as shown in FIG. 30. the top one of the dummy semiconductor layers 124 in FIG. 9 may act as an etch stop layer. Accordingly, after the etching, the top one of the dummy semiconductor layers 124 is exposed. The resulting structure is shown in FIG. 10.

Next, the top one (the etch stop layer) of the dummy semiconductor layers 124 is removed in an etching process, which may be anisotropic or isotropic. The respective process is illustrated as process 232 in the process flow 200 as shown in FIG. 30. The etching is performed using an etching chemical (gas or wet etching solution) that etches dummy semiconductor layer 124 faster than etching semiconductor nanostructures 26. Accordingly, the top one of semiconductor nanostructures 126 acts as the etch stop layer. The resulting structure is shown in FIG. 11.

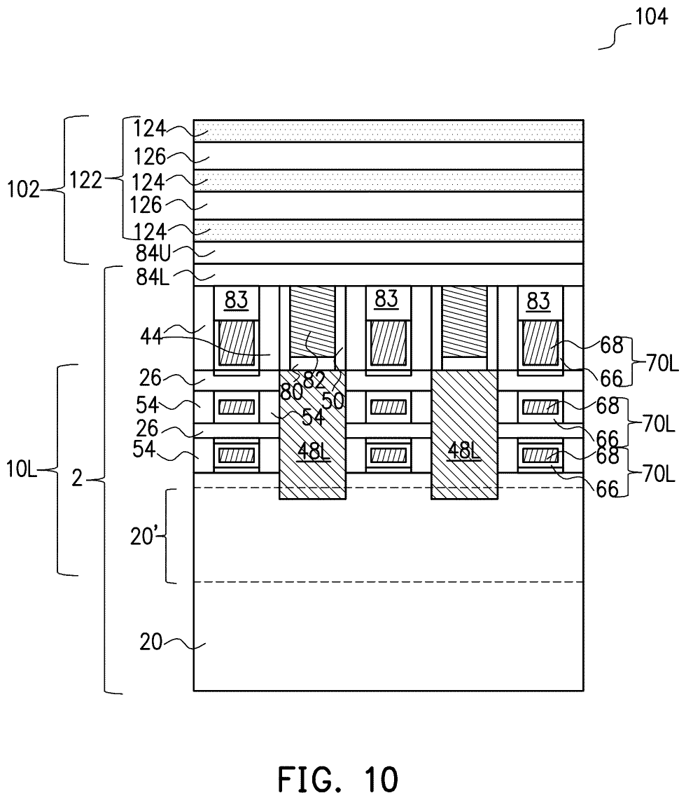

FIG. 12 illustrates the patterning of multi-layer stack 122 in a patterning process, which includes an anisotropic etching process. The respective process is illustrated as process 234 in the process flow 200 as shown in FIG. 30. Bond layer 84U may act as the etch top layer. Accordingly, a plurality of strips of multi-layer stack 122 are formed, with the lengthwise direction of the strips of multi-layer stack 122 being perpendicular to the illustrated plane.

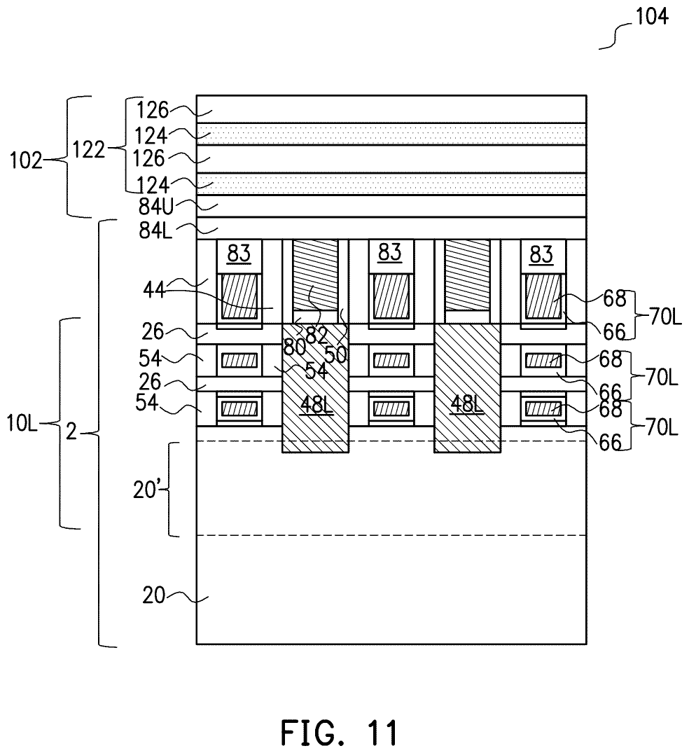

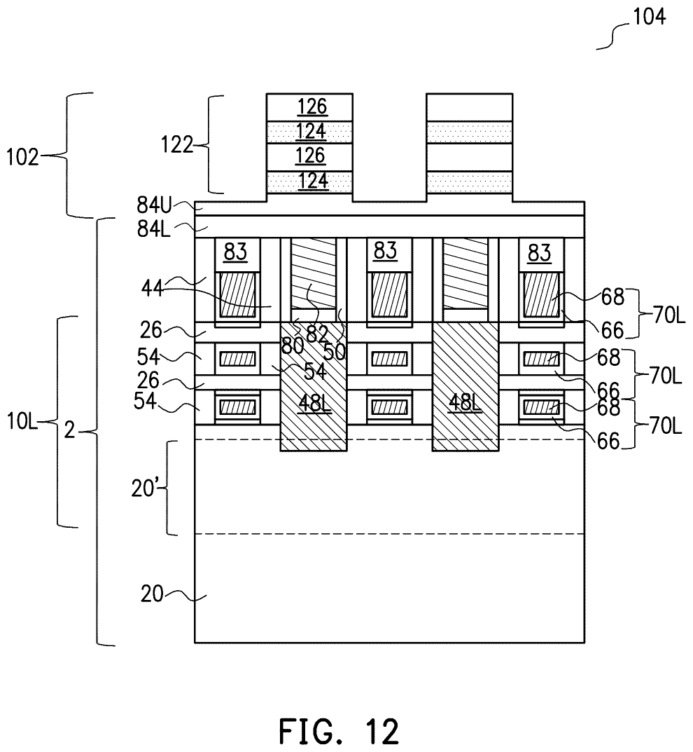

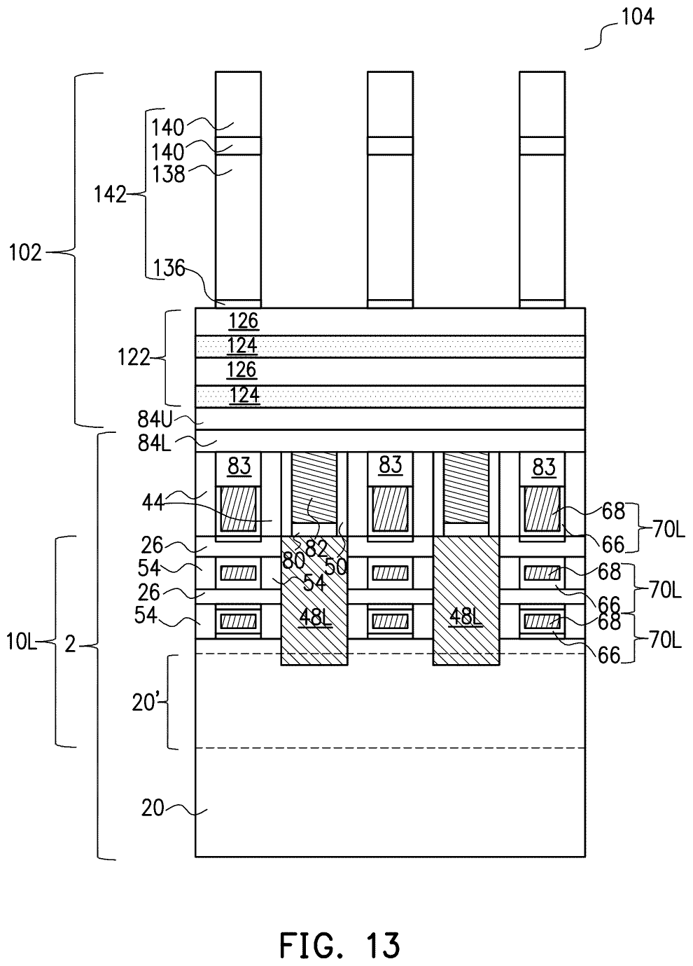

FIG. 13 illustrates the formation of dummy gate stacks 142, which includes dummy gate dielectrics 136, dummy gate electrodes 138, and mask layers 140. The respective process is illustrated as process 236 in the process flow 200 as shown in FIG. 30.

Next, as shown in FIG. 14, gate spacers 144 are formed, followed by the formation of inner spacers 154, upper source/drain regions 48U, CESL 150, and ILD 152. The respective processes are illustrated as processes 238, 240, and 242 in the process flow 200 as shown in FIG. 30. The formation processes may be essentially the same as the formation of the corresponding features in lower wafer 2, and may be found in the discussion of FIGS. 3-5. In accordance with some embodiments, upper source/drain regions 48U has an opposite conductivity type than lower source/drain regions 48L. For example, when lower source/drain regions 48L is doped with a p-type dopant, the upper source/drain regions 48U is doped with an n-type dopant, and vice versa.

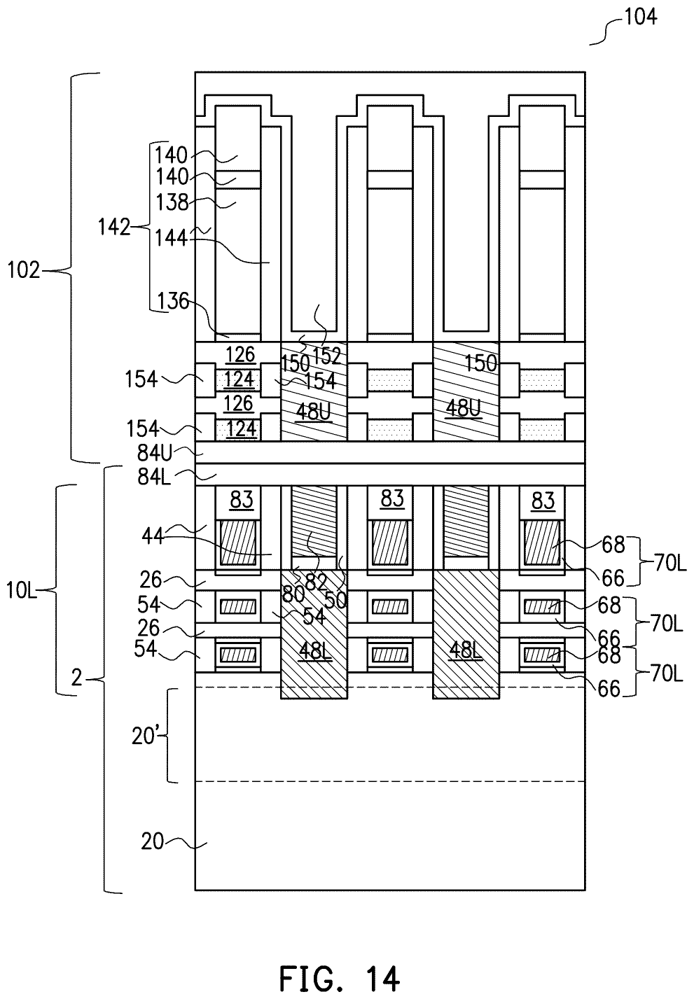

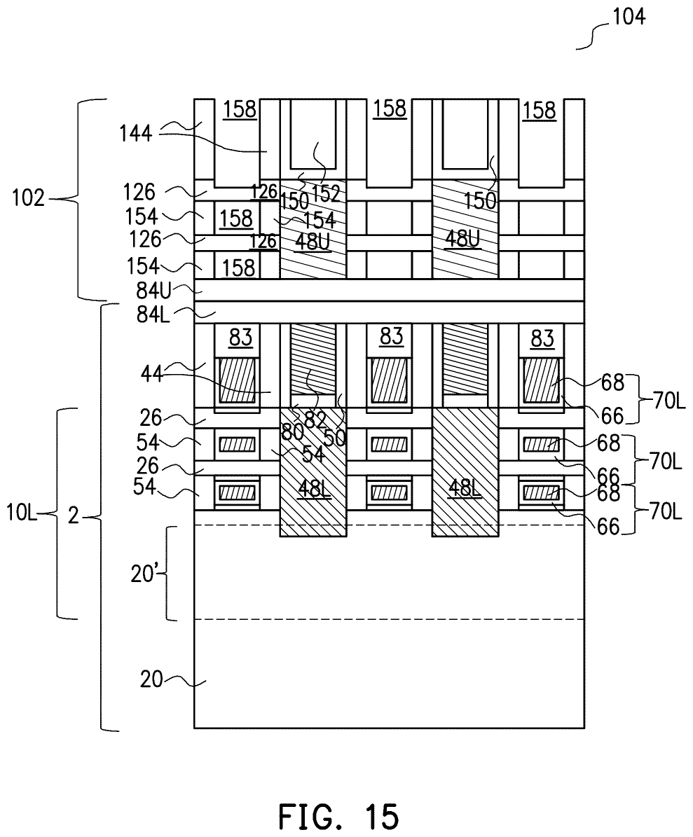

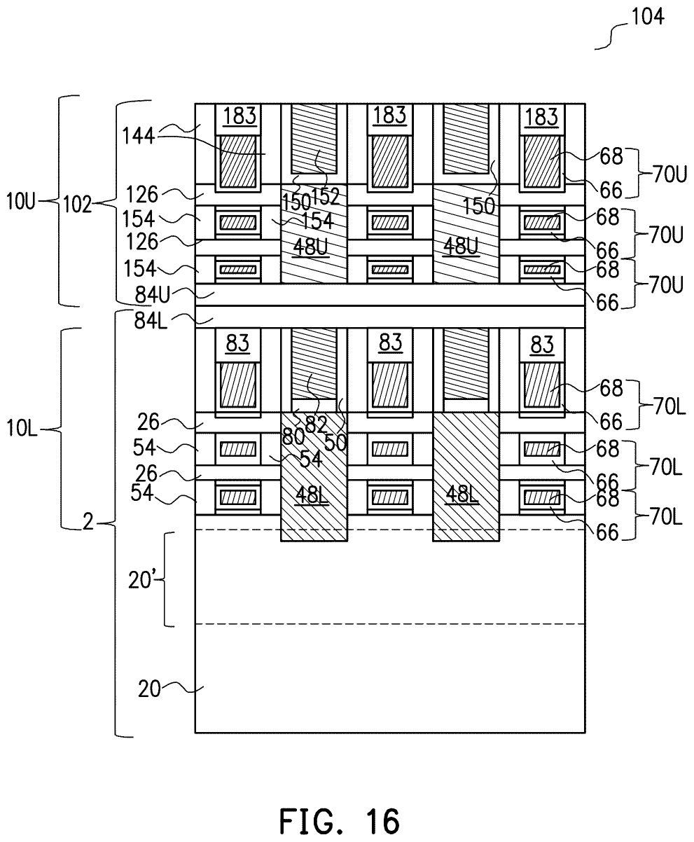

The dummy gate stacks 142 and dummy semiconductor layers 124 are then removed, hence forming recesses 158 as show in FIG. 15. The respective process is illustrated as process 244 in the process flow 200 as shown in FIG. 30. In subsequent processes, as shown in FIG. 16, replacement gate stacks 70U are formed, hence forming the corresponding upper transistor 10U. The respective process is illustrated as process 246 in the process flow 200 as shown in FIG. 30. The formation process 246 may be essentially the same as what is illustrated in the processes as shown in FIGS. 18 through 22, and is also shown in the process 300 as in FIG. 31. The details of the processes are not repeated herein.

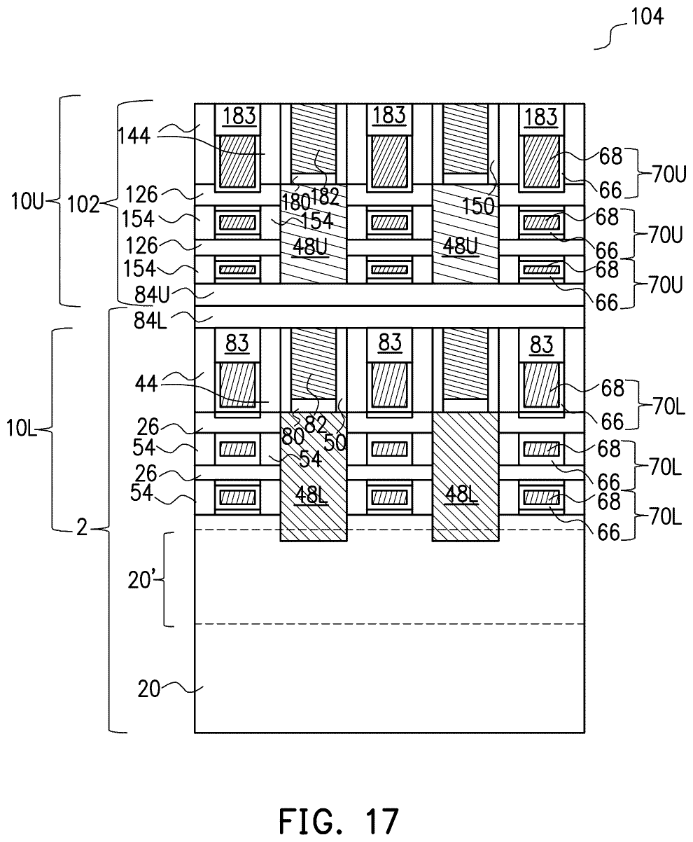

After the formation of replacement gate stacks 70U, the replacement gate stacks 70U are recessed, and dielectric hard masks 183 are formed in the corresponding recesses. FIG. 17 illustrates the formation of source/drain silicide layer 180 and source/drain contact plug 182.

In accordance with some embodiments, the gate dielectrics 66 in lower transistor 10L is formed using the processes shown in FIGS. 23-27. Accordingly, the drive-in process 74 (FIG. 25) is performed at an elevated temperature. The corresponding thermal budget, however, does not affect the subsequent formation of the upper transistor 10U. The dipole dopant doping process of the upper transistor 10U, on the other hand, may adopt the process shown in FIGS. 18-22, and hence there is zero (or low) thermal budget, and hence the adverse effect of thermal budget in the doping of dipole dopant to the lower transistor 10L is reduced or eliminated.

In accordance with alternative embodiments, the dipole dopant doping processes of both of the lower transistor 10L and the upper transistor 10U may be performed using the processes shown in FIGS. 18-22 to further reduce the thermal budget.

The embodiments of the present disclosure have some advantageous features. By forming a dipole film between interfacial layer and high-k dielectric of a gate dielectric, no drive-in process is needed, and no dipole film removal process is needed. The manufacturing cost of the CFETs is thus reduced. Also, the low or zero thermal budget used by the dipole dopant doping process of the upper transistor is beneficial to the lower transistor.

In accordance with some embodiments of the present disclosure, a method comprises forming a first transistor comprising forming a first semiconductor nanostructure; forming a first interfacial layer encircling the first semiconductor nanostructure; depositing a first dipole film on the first interfacial layer; depositing a first high-k dielectric layer on the first dipole film; and depositing a first gate electrode on the first high-k dielectric layer. In an embodiment, the method further comprises forming a second transistor, wherein the first transistor overlaps the second transistor, and the forming the second transistor comprises forming a second semiconductor nanostructure; forming a second interfacial layer encircling the second semiconductor nanostructure; depositing a second high-k dielectric layer on the second interfacial layer; depositing a second dipole film on the second high-k dielectric layer; driving-in a dipole dopant in the second dipole film into the second high-k dielectric layer; removing the second dipole film; and depositing a second gate electrode on the second high-k dielectric layer.

In an embodiment, the method further comprises forming a second transistor, wherein the first transistor overlaps the second transistor, and the forming the second transistor comprises forming a second semiconductor nanostructure; forming a second interfacial layer encircling the second semiconductor nanostructure; depositing a second dipole film on the second interfacial layer; depositing a second high-k dielectric layer on the second dipole film; and depositing a second gate electrode on the second high-k dielectric layer.

In an embodiment, the method further comprises forming a second transistor comprising forming a second semiconductor nanostructure; forming a second interfacial layer encircling the second semiconductor nanostructure; depositing a second dipole film on the second interfacial layer, wherein the first dipole film and the second dipole film are deposited in a same deposition process; removing the second dipole film; depositing a second high-k dielectric layer over and contacting the second interfacial layer; and depositing a second gate electrode on the second high-k dielectric layer.

In an embodiment, at a time when the first gate electrode is deposited, the first dipole film remains between the first interfacial layer and the first high-k dielectric layer. In an embodiment, in an entire period of time starting at a first time the first dipole film is deposited and ending at a second time the first gate electrode has been formed, no drive-in process is performed to drive dipole dopants in the first dipole film into the first interfacial layer. In an embodiment, until a time after the first gate electrode has been deposited, no removal process is performed to remove the first dipole film. In an embodiment, a peak dipole dopant of the first dipole film is in middle between the first interfacial layer and the first high-k dielectric layer. In an embodiment, the first dipole film has a thickness smaller than about 1 Å.

In an embodiment, the method further comprises forming a source/drain region on a side of the first semiconductor nanostructure, wherein the source/drain region is of n-type, the first gate electrode comprises a p-type work-function layer, and the first dipole film comprises an n-type dipole dopant. In an embodiment, the method further comprises forming a source/drain region on a side of the first semiconductor nanostructure, wherein the source/drain region is of p-type, the first gate electrode comprises an n-type work-function layer, and the first dipole film comprises a p-type dipole dopant.

In accordance with some embodiments of the present disclosure, a structure comprises a first transistor comprising a first semiconductor nanostructure; a first source region and a first drain region on opposing sides, and joined to, the first semiconductor nanostructure; and a first gate stack encircling the first semiconductor nanostructure, wherein the first gate stack comprises a first interfacial layer; a first high-k dielectric layer on the first interfacial layer, wherein the first interfacial layer and the first high-k dielectric layer comprise a first dipole dopant, and a first peak concentration of the first dipole dopant is in middle between the first interfacial layer and the first high-k dielectric layer; and a first gate electrode on the first high-k dielectric layer.

In an embodiment, the first interfacial layer joins the first high-k dielectric layer, and the first peak concentration is at an interface of the first interfacial layer and the first high-k dielectric layer. In an embodiment, the structure further comprises a dipole film comprising the first dipole dopant, wherein the dipole film is between the first interfacial layer and the first high-k dielectric layer.

In an embodiment, the structure further comprises a second transistor overlapped by the first transistor, wherein the second transistor comprises a second semiconductor nanostructure; and a second gate stack encircling the second semiconductor nanostructure, wherein the second gate stack comprises a second interfacial layer; a second high-k dielectric layer on the second interfacial layer, wherein the first interfacial layer and the first high-k dielectric layer comprise a second dipole dopant; and a second gate electrode on the second high-k dielectric layer, wherein a second peak concentration of the second dipole dopant is at an interface between the second high-k dielectric layer and the second gate electrode.

In an embodiment, in directions pointing from the middle between the first interfacial layer and the first high-k dielectric layer into the first interfacial layer and the first high-k dielectric layer, concentrations of the first dipole dopant reduce gradually. In an embodiment, the structure further comprises a second transistor at a same level as the first transistor, wherein the second transistor comprises a second interfacial layer and a second high-k dielectric layer on the second interfacial layer, and wherein the second interfacial layer and the second high-k dielectric layer are free from the first dipole dopant.

In accordance with some embodiments of the present disclosure, a structure comprises a lower transistor comprising a first gate stack, wherein the first gate stack comprises a first interfacial layer; a first high-k dielectric layer on the first interfacial layer; and a first gate electrode on the first high-k dielectric layer, wherein the first high-k dielectric layer and the first gate electrode comprise a first dipole dopant, and a first peak concentration of the first dipole dopant is at an interface between the first high-k dielectric layer and the first gate electrode; and an upper transistor overlapping the lower transistor, wherein the upper transistor comprises a second gate stack comprising a second interfacial layer; a second high-k dielectric layer on the second interfacial layer, wherein the second interfacial layer and the second high-k dielectric layer comprise a second dipole dopant, and a second peak concentration of the second dipole dopant is in middle between the second interfacial layer and the second high-k dielectric layer; and a second gate electrode on the second high-k dielectric layer.

In an embodiment, the lower transistor has an opposite conductivity type than the upper transistor. In an embodiment, the structure further comprises an additional upper transistor comprising an additional interfacial layer and an additional high-k dielectric layer on the additional interfacial layer, wherein the additional interfacial layer and the additional high-k dielectric layer are free from the second dipole dopant therein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first transistor comprising:
forming a first semiconductor nanostructure;
forming a first interfacial layer encircling the first semiconductor nanostructure;
depositing a first dipole film on the first interfacial layer;
depositing a first high-k dielectric layer on the first dipole film; and
depositing a first gate electrode on the first high-k dielectric layer.

2. The method of claim 1 further comprising forming a second transistor, wherein the first transistor overlaps the second transistor, and the forming the second transistor comprises:
forming a second semiconductor nanostructure;
forming a second interfacial layer encircling the second semiconductor nanostructure;
depositing a second high-k dielectric layer on the second interfacial layer;
depositing a second dipole film on the second high-k dielectric layer;
driving-in a dipole dopant in the second dipole film into the second high-k dielectric layer;
removing the second dipole film; and
depositing a second gate electrode on the second high-k dielectric layer.

3. The method of claim 1 further comprising forming a second transistor, wherein the first transistor overlaps the second transistor, and the forming the second transistor comprises:
forming a second semiconductor nanostructure;
forming a second interfacial layer encircling the second semiconductor nanostructure;
depositing a second dipole film on the second interfacial layer;
depositing a second high-k dielectric layer on the second dipole film; and
depositing a second gate electrode on the second high-k dielectric layer.

4. The method of claim 1 further comprising forming a second transistor comprising:
forming a second semiconductor nanostructure;
forming a second interfacial layer encircling the second semiconductor nanostructure;
depositing a second dipole film on the second interfacial layer, wherein the first dipole film and the second dipole film are deposited in a same deposition process;
removing the second dipole film;
depositing a second high-k dielectric layer over and contacting the second interfacial layer; and
depositing a second gate electrode on the second high-k dielectric layer.

5. The method of claim 1, wherein at a time when the first gate electrode is deposited, the first dipole film remains between the first interfacial layer and the first high-k dielectric layer.

6. The method of claim 1, wherein in an entire period of time starting at a first time the first dipole film is deposited and ending at a second time the first gate electrode has been formed, no drive-in process is performed to drive dipole dopants in the first dipole film into the first interfacial layer.

7. The method of claim 1, wherein until a time after the first gate electrode has been deposited, no removal process is performed to remove the first dipole film.

8. The method of claim 1, wherein a peak dipole dopant of the first dipole film is in middle between the first interfacial layer and the first high-k dielectric layer.

9. The method of claim 1, wherein the first dipole film has a thickness smaller than about 1 Å.

10. The method of claim 1 further comprising forming a source/drain region on a side of the first semiconductor nanostructure, wherein the source/drain region is of n-type, the first gate electrode comprises a p-type work-function layer, and the first dipole film comprises an n-type dipole dopant.

11. The method of claim 1 further comprising forming a source/drain region on a side of the first semiconductor nanostructure, wherein the source/drain region is of p-type, the first gate electrode comprises an n-type work-function layer, and the first dipole film comprises a p-type dipole dopant.

12. A structure comprising:
a first transistor comprising:
a first semiconductor nanostructure;
a first source region and a first drain region on opposing sides, and joined to, the first semiconductor nanostructure; and
a first gate stack encircling the first semiconductor nanostructure, wherein the first gate stack comprises:
a first interfacial layer;
a first high-k dielectric layer on the first interfacial layer, wherein the first interfacial layer and the first high-k dielectric layer comprise a first dipole dopant, and a first peak concentration of the first dipole dopant is in middle between the first interfacial layer and the first high-k dielectric layer; and
a first gate electrode on the first high-k dielectric layer.

13. The structure of claim 12, wherein the first interfacial layer joins the first high-k dielectric layer, and the first peak concentration is at an interface of the first interfacial layer and the first high-k dielectric layer.

14. The structure of claim 12 further comprising a dipole film comprising the first dipole dopant, wherein the dipole film is between the first interfacial layer and the first high-k dielectric layer.

15. The structure of claim 12 further comprising a second transistor overlapped by the first transistor, wherein the second transistor comprises:
a second semiconductor nanostructure; and
a second gate stack encircling the second semiconductor nanostructure, wherein the second gate stack comprises:
a second interfacial layer;
a second high-k dielectric layer on the second interfacial layer, wherein the first interfacial layer and the first high-k dielectric layer comprise a second dipole dopant; and
a second gate electrode on the second high-k dielectric layer, wherein a second peak concentration of the second dipole dopant is at an interface between the second high-k dielectric layer and the second gate electrode.

16. The structure of claim 12, wherein in directions pointing from the middle between the first interfacial layer and the first high-k dielectric layer into the first interfacial layer and the first high-k dielectric layer, concentrations of the first dipole dopant reduce gradually.

17. The structure of claim 12 further comprising a second transistor at a same level as the first transistor, wherein the second transistor comprises a second interfacial layer and a second high-k dielectric layer on the second interfacial layer, and wherein the second interfacial layer and the second high-k dielectric layer are free from the first dipole dopant.

18. A structure comprising:
a lower transistor comprising a first gate stack, wherein the first gate stack comprises:
a first interfacial layer;
a first high-k dielectric layer on the first interfacial layer; and
a first gate electrode on the first high-k dielectric layer, wherein the first high-k dielectric layer and the first gate electrode comprise a first dipole dopant, and a first peak concentration of the first dipole dopant is at an interface between the first high-k dielectric layer and the first gate electrode; and
an upper transistor overlapping the lower transistor, wherein the upper transistor comprises a second gate stack comprising:
a second interfacial layer;
a second high-k dielectric layer on the second interfacial layer, wherein the second interfacial layer and the second high-k dielectric layer comprise a second dipole dopant, and a second peak concentration of the second dipole dopant is in middle between the second interfacial layer and the second high-k dielectric layer; and
a second gate electrode on the second high-k dielectric layer.

19. The structure of claim 18, wherein the lower transistor has an opposite conductivity type than the upper transistor.

20. The structure of claim 18 further comprising an additional upper transistor comprising an additional interfacial layer and an additional high-k dielectric layer on the additional interfacial layer, wherein the additional interfacial layer and the additional high-k dielectric layer are free from the second dipole dopant therein.
